(19) United States
(12) Patent Application Publication
(10) Pub. No.: US 2026/0354062 A1
(43) Pub. Date: Nov. 5, 2026

(54) METHOD FOR FORMING JUNCTION AND DEFECT STRUCTURE OF TWO-DIMENSIONAL THIN FILM MATERIAL BY USING OPTICAL SOLDERING, AND JUNCTION AND DEFECT STRUCTURE THEREFOR

(71) Applicant: KOREA RESEARCH INSTITUTE OF CHEMICAL TECHNOLOGY, Daejeon (KR)

(72) Inventor: Hyun-Woo KIM, Daejeon (KR)

(73) Assignee: KOREA RESEARCH INSTITUTE OF CHEMICAL TECHNOLOGY, Daejeon (KR)

(21) Appl. No.: 19/102,709

(22) PCT Filed: Jul. 31, 2023
(86) PCT No.: PCT/KR2023/011147

§ 371 Date: Feb. 10, 2025

(30) Foreign Application Priority Data
Aug. 11, 2022 (KR) 10-2022-0100492

(51) Int. Cl. H10P 34/42; H10D 62/80

(52) U.S. Cl. CPC H10P 34/42; H10D 62/883

(57) ABSTRACT

The objective of the present invention is to provide a method for forming a junction and defect structure of a two-dimensional thin film material by using optical soldering, and a junction and defect structure therefor, the method forming a defect structure by using optical soldering in which nanoparticles are used as a soldering material at a desired local position of a two-dimensional single-layer or a multi-layer thin film semiconductor material. In order to achieve the objective, the method for forming a junction and defect structure of a two-dimensional thin film material by using optical soldering, of the present invention, comprises: a first step in which a two-dimensional thin film semiconductor layer is topped on particles or a structure; a second step of emitting a laser at a desired local position of the two-dimensional thin film semiconductor layer; a third step in which the temperature of the two-dimensional thin film semiconductor layer is increased through optical heating using laser emission; and a fourth step in which heat transformation at the particles or the structure occurs by means of heat transfer, due to the increased temperature, in the two-dimensional thin film semiconductor layer.

### TECHNICAL FIELD

The present disclosure relates to a method for forming junction and defect structure of two-dimensional thin film material using optical soldering, and junction and defect structures therefor. More specifically, the present disclosure pertains to a method for forming defect structures at designated local positions of two-dimensional monolayer or multilayer thin film semiconductor materials using optical soldering, and to the junctions and the defect structures formed through such optical soldering.

### BACKGROUND ART

A two-dimensional transition metal dichalcogenide (TMD) compound, which is one of the two-dimensional thin film semiconductor materials, is a material that absorbs light within specific wavelength ranges and converts the light into electric current.

In particular, two-dimensional transition metal dichalcogenide (TMD) compounds are under active studies for applications in semiconductor and optical devices due to their optoelectronic properties, such as direct bandgap opening at wide spectral range, highly efficient photoluminescence (PL) emission, exciton and trion physics having strong binding energy, and spin valley control enabled by circularly polarized beams.

In addition, the local manipulation of optoelectronic properties in two-dimensional (2D) transition metal dichalcogenide (TMD) compounds is achievable through various mechanisms. These mechanisms include exciton funneling into local strain induced sites (e.g., tips, nanostructures, nanobubbles), optical induced phase transitions, or Moire lattice of stacked 2D TMD promising novel applications such as single photon emission, optical switch, single atom memory, and ultrasensitive sensing.

Therefore, defect structure formation by laser irradiation is facile approach for local manipulation of the two-dimensional transition metal dichalcogenides because it provides site-selective and real-time fabrication capability.

However, accumulation of thermal energy is required to induce layer number reduction (ablation), atom composition (phase transition), or chemical adsorption (photoreaction) of the two-dimensional transition metal dichalcogenides by laser irradiation.

Therefore, forming defect structures or inducing phase transitions in two-dimensional transition metal dichalcogenide compounds requires high incident optical power and long irradiation durations.

However, such high incident power and prolonged irradiation present challenges in preserving the high quality of two-dimensional transition metal dichalcogenides required for optoelectronic applications.

That is, methods for defect formation using laser irradiation has the problem that high-power lasers or prolonged laser exposure could potentially damage the two-dimensional semiconductor materials.

### DISCLOSURE

### Technical Problem

The purpose of the present disclosure, which addresses the aforementioned conventional problems, is to provide a method for forming junctions and defect structures in two-dimensional thin film materials using optical soldering, wherein nanoparticles are employed as soldering materials to form defect structures at designated local positions of two-dimensional monolayer or multilayer thin film semiconductor materials, as well as to provide the junctions and the defect structures.

In addition, the present disclosure provides a method for forming junctions and defect structures in two-dimensional thin film materials using optical soldering, as well as the junctions and the defect structures formed by using optical soldering.

In addition, the present disclosure provides a technique for the junction (soldering, bonding, etc.) of two-dimensional thin film materials using incident light.

Meanwhile, the soldering junction of the two-dimensional thin film semiconductor according to the present disclosure can provide electrical junctions (contacts), such as forming contacts with other materials, local defect fabrication for controlling optoelectronic properties, and localized trapping of chemical molecular species, including adsorption singularities of chemical molecular species.

### Technical Solution

In order to achieve the purpose, an aspect of the present disclosure provides a method for forming junction and defect structure of two-dimensional thin film material by using optical soldering, the method comprising: a first step in which a two-dimensional thin film semiconductor layer is topped on a particle or a structure; a second step of irradiating laser at a designated local position of the two-dimensional thin film semiconductor layer; a third step in which a temperature of the two-dimensional thin film semiconductor layer increases through optical heating by irradiation of the laser; and a fourth step in which thermal deformation occurs in the particle or the structure due to heat transfer of the two-dimensional thin film semiconductor layer by the temperature increased.

In some exemplary embodiments, the method may further comprise a fifth step in which the two-dimensional thin film semiconductor layer is bonded to the particle or the structure in which the thermal deformation occurs.

In some exemplary embodiments, the method may further comprise a sixth step in which the two-dimensional thin film semiconductor layer bonded to the particle or the structure is pulled in a direction where the thermal deformation occurs.

In some exemplary embodiments, the method may further comprise a seventh step in which a crack occurs on both sides of the pulled particle or the pulled structure.

In some exemplary embodiments, the particle may be a nanoparticle or a microparticle.

In some exemplary embodiments, the structure may be a nanostructure or a microstructure.

In some exemplary embodiments, the two-dimensional thin film semiconductor layer may be monolayered or multilayered.

In some exemplary embodiments, the particle may be a nanoparticle that melts at a temperature at which the two-dimensional thin film semiconductor can be heated by absorption of light.

In some exemplary embodiments, the particle or the structure not subjected to optical irradiation by the laser may maintain a shape and a height to support the two-dimensional thin film semiconductor layer.

In some exemplary embodiments, the two-dimensional thin film semiconductor layer is a thin film material in which absorption of light occurs.

In some exemplary embodiments, wherein an incident power of the laser may be between 2.5 mW and 15 mW or less, and an incident time of the laser may be 30 seconds or less.

In some exemplary embodiments, the particle or the structure may be formed by depositing a transparent electrode layer on a base substrate and then performing one of wet etching, nanoparticle spraying, or nanostructure formation.

In some exemplary embodiments, a material of the transparent electrode layer may be an indium or an alloy containing the indium.

In addition, in order to achieve the purpose, another aspect of the present disclosure provides a defect structure formed by the method for forming junction and defect structure of two-dimensional thin film material by using optical soldering.

In addition, in order to achieve the purpose, still another aspect of the present disclosure provides a junction and a defect structure of two-dimensional thin film material by using optical soldering, characterized in that: by optical heating induced by irradiation of laser at a designated local position of a two-dimensional thin film semiconductor layer topped with a particle or a structure, thermal deformation occurs in the particle or the structure due to transfer of heat generated in the two-dimensional thin film semiconductor layer.

In some exemplary embodiments, the two-dimensional thin film semiconductor layer may be bonded to the particle or the structure in which the thermal deformation occurs.

In some exemplary embodiments, the two-dimensional thin film semiconductor layer bonded to the particle or the structure may be pulled in a direction where the thermal deformation occurs.

In some exemplary embodiments, a crack may occur on both sides of the pulled particle or the pulled structure.

Specific details of other exemplary embodiments are included in “Details for carrying out the invention” and accompanying “drawings”.

Advantages and/or features of the present disclosure, and a method for achieving the advantages and/or features will become obvious with reference to various exemplary embodiments to be described below in detail together with the accompanying drawings.

However, the present disclosure is not limited only to a configuration of each exemplary embodiment disclosed below, but may also be implemented in various different forms. The respective exemplary embodiments disclosed in this specification are provided only to complete disclosure of the present disclosure and to fully provide those skilled in the art to which the present disclosure pertains with the category of the present disclosure, and the present disclosure will be defined only by the scope of each claim of the claims.

### Advantageous Effects

According to an exemplary embodiment of the present disclosure, defect structures can be formed by using optical soldering, where nanoparticles are employed as soldering materials at designated local positions of two-dimensional monolayer or multilayer thin film semiconductor materials.

In addition, according to an exemplary embodiment of the present disclosure, the local junction (soldering) of two-dimensional thin film materials can be feasible by using focused light.

Furthermore, according to an exemplary embodiment of the present disclosure, by joining two-dimensional materials, electrical contact, chemical molecular trapping, and optoelectronic property modulation can be feasible at the designated positions.

In addition, according to an exemplary embodiment of the present disclosure, the soldering material beneath the two-dimensional material can take various forms, including nanoparticles, nanostructures, and thin films.

### DESCRIPTION OF DRAWINGS

FIG. 1 is a flowchart illustrating the overall process of the method for forming junctions and defect structures in two-dimensional thin film materials using optical soldering according to an exemplary embodiment of the present disclosure.

FIG. 2 is a diagram showing the state in which a two-dimensional thin film semiconductor layer is topped on a particle or a structure, in the method for forming junctions and defect structures in two-dimensional thin film materials using optical soldering according to an exemplary embodiment of the present disclosure.

FIG. 3 is a diagram illustrating the state in which laser irradiation is applied to a designated local position of the two-dimensional thin film semiconductor layer, and the temperature of the layer increases due to optical heating induced by the laser irradiation, in the method for forming junctions and defect structures in two-dimensional thin film materials using optical soldering according to an exemplary embodiment of the present disclosure.

FIG. 4 is a diagram showing the state in which thermal deformation occurs in the particles or structure due to heat transfer from the heated two-dimensional thin film semiconductor layer, in the method for forming junctions and defect structures in two-dimensional thin film materials using optical soldering according to an exemplary embodiment of the present disclosure.

FIG. 5 is a diagram illustrating the state in which the two-dimensional thin film semiconductor layer adheres to the thermally deformed particles or structure, in the method for forming junctions and defect structures in two-dimensional thin film materials using optical soldering according to an exemplary embodiment of the present disclosure.

FIG. 6 is a diagram depicting the state in which the two-dimensional thin film semiconductor layer attached to the particles or structure is pulled in the direction of thermal deformation (indicated by arrows), in the method for forming junctions and defect structures in two-dimensional thin film materials using optical soldering according to an exemplary embodiment of the present disclosure.

FIG. 7 is a diagram showing the state in which cracks are formed on both sides of the pulled particles or structure, in the method for forming junctions and defect structures in two-dimensional thin film materials using optical soldering according to an exemplary embodiment of the present disclosure.

FIG. 8 is a schematic diagram illustrating the concept of optical soldering of several layers of MoS₂ on indium-tin-oxide (ITO) nanoparticles (NPs) for defect structure formation, in the method for forming junctions and defect structures in two-dimensional thin film materials using optical soldering according to an exemplary embodiment of the present disclosure.

FIG. 9 is a scanning electron microscope (SEM) image of indium-tin-oxide nanoparticles with a scale bar of 500 nm, in the method for forming junctions and defect structures in two-dimensional thin film materials using optical soldering according to an exemplary embodiment of the present disclosure.

FIG. 10 is an atomic force microscope (AFM) image of indium-tin-oxide nanoparticles embedded with several layers of MoS₂ on top, in the method for forming junctions and defect structures in two-dimensional thin film materials using optical soldering according to an exemplary embodiment of the present disclosure.

FIG. 11 is an image captured in the bright field (BF) mode.

FIG. 12 is an atomic force microscope (AFM) image showing the defect structures induced by optical soldering after irradiation with a focused 532 nm laser for 15 seconds at different incident power levels of 0.5 mW, 1 mW, 3 mW, 10 mW, and 15 mW along an arrowed path, in the method for forming junctions and defect structures in two-dimensional thin film materials using optical soldering according to an exemplary embodiment of the present disclosure.

FIG. 13 is a diagram illustrating the atomic force microscope morphology of the MoS₂ layer processed through optical soldering, in the method for forming junctions and defect structures in two-dimensional thin film materials using optical soldering according to an exemplary embodiment of the present disclosure.

FIG. 14 is a graph showing the cross-sectional profile obtained along the black dotted line in the central region of the defect structure, in the method for forming junctions and defect structures in two-dimensional thin film materials using optical soldering according to an exemplary embodiment of the present disclosure.

FIG. 15 is a transmission electron microscope (TEM) image of the cross-section of an indium-tin-oxide nanoparticle with several embedded layers of MoS₂ before laser irradiation, in the method for forming junctions and defect structures in two-dimensional thin film materials using optical soldering according to an exemplary embodiment of the present disclosure.

FIG. 16 is a transmission electron microscope (TEM) image of the cross-section of an indium-tin-oxide nanoparticle with several embedded layers of MoS₂ after laser irradiation, in the method for forming junctions and defect structures in two-dimensional thin film materials using optical soldering according to an exemplary embodiment of the present disclosure.

### BEST MODE

The present disclosure provides a method for forming junctions and defect structures in two-dimensional thin film materials using optical soldering, wherein nanoparticles are employed as soldering materials to form defect structures at designated local positions of two-dimensional monolayer or multilayer thin film semiconductor materials, as well as to provide the junctions and the defect structures.

In addition, the present disclosure provides a method for forming junctions and defect structures in two-dimensional thin film materials using optical soldering, as well as the junctions and the defect structures formed by using optical soldering.

In addition, the present disclosure provides a technique for the junction (soldering, bonding, etc.) of two-dimensional thin film materials using incident light.

Meanwhile, the soldering junction of the two-dimensional thin film semiconductor according to the present disclosure can provide electrical junctions (contacts), such as forming contacts with other materials, local defect fabrication for controlling optoelectronic properties, and localized trapping of chemical molecular species, including adsorption singularities of chemical molecular species.

### Mode for Invention

Before describing the present disclosure in detail, the terms or words used in this specification should not be construed as being unconditionally limited to their ordinary or dictionary meanings, and in order for the inventor of the present disclosure to describe his/her disclosure in the best way, concepts of various terms may be appropriately defined and used, and furthermore, the terms or words should be construed as means and concepts which are consistent with a technical idea of the present disclosure.

That is, the terms used in this specification are only used to describe preferred embodiments of the present disclosure, and are not used for the purpose of specifically limiting the contents of the present disclosure, and it should be noted that the terms are defined by considering various possibilities of the present disclosure.

Further, in this specification, it should be understood that, unless the context clearly indicates otherwise, the expression in the singular may include a plurality of expressions, and similarly, even if it is expressed in plural, it should be understood that the meaning of the singular may be included.

In the case where it is stated throughout this specification that a component “includes” another component, it does not exclude any other component, but may further include any other component unless otherwise indicated.

Furthermore, it should be noted that when it is described that a component “exists in or is connected to” another component, this component may be directly connected or installed in contact with another component, and in inspect to a case where both components are installed spaced apart from each other by a predetermined distance, a third component or means for fixing or connecting the corresponding component to the other component may exist, and the description of the third component or means may be omitted.

On the contrary, when it is described that a component is “directly connected to” or “directly accesses” to another component, it should be understood that the third element or means does not exist.

Similarly, it should be construed that other expressions describing the relationship of the components, that is, expressions such as “between” and “directly between” or “adjacent to” and “directly adjacent to” also have the same purpose.

In addition, it should be noted that if terms such as “one side surface”, “other side surface”, “one side”, “other side”, “first”, “second”, etc., are used in this specification, the terms are used to clearly distinguish one component from the other component and a meaning of the corresponding component is not limited used by the terms.

Further, in this specification, if terms related to locations such as “upper”, “lower”, “left”, “right”, etc., are used, it should be understood that the terms indicate a relative location in the drawing with respect to the corresponding component and unless an absolute location is specified for their locations, these location-related terms should not be construed as referring to the absolute location.

Further, in this specification, in specifying the reference numerals for each component of each drawing, the same component has the same reference number even if the component is indicated in different drawings, that is, the same reference number indicates the same component throughout the specification.

In the drawings attached to this specification, a size, a location, a coupling relationship, etc. of each component constituting the present disclosure may be described while being partially exaggerated, reduced, or omitted for sufficiently clearly delivering the spirit of the present disclosure, and thus the proportion or scale may not be exact.

Further, hereinafter, in describing the present disclosure, a detailed description of a configuration determined that may unnecessarily obscure the subject matter of the present disclosure, for example, a detailed description of a known technology including the prior art may be omitted.

Hereinafter, exemplary embodiments of the present disclosure will be described in detail with reference to related drawings.

### —Definition of Optical Soldering—

Optical soldering (optical junction) refers to the deformation of indium-tin-oxide (ITO) nanoparticles (NPs) due to heat energy transfer from optically heated MoS₂ multilayers when irradiated with a laser. In this process, MoS₂ multilayers are topped (coated) onto ITO nanoparticles, and upon laser irradiation, the generated heat causes the underlying ITO nanoparticles to undergo thermal deformation.

In exemplary embodiments of the present disclosure, for ease of explanation, indium nanoparticles are fabricated by wet-etching an indium-tin-oxide film. However, the present disclosure is not limited to this method, as the primary component of the nanoparticles is indium. The nanoparticles may include indium nanoparticles, indium-tin nanoparticles, or indium-tin-oxide nanoparticles, among other indium-based or indium-containing alloy nanoparticles.

Here, “topping” refers to the simple placement of an MoS₂ layer onto ITO nanoparticles.

Defect structures induced by optical soldering exhibit unique optoelectronic properties, which can be confirmed in the original MoS₂ layer, not only in terms of surface morphology but also through unexpected photoluminescence (PL) emission from the few-layered two-dimensional transition metal dichalcogenide (TMD) compound.

In the present disclosure, in order to elucidate the fundamental mechanism of optical soldering that forms localized defect structures with modified optoelectronic properties, the optical soldering process is systematically investigated using dependencies on incident light power and irradiation duration.

In addition, the present disclosure provides a method for forming junctions and defect structures in two-dimensional thin film materials using optical soldering, as well as the junctions and the defect structures formed by using optical soldering.

In particular, the present disclosure provides a technique for the junction (soldering, bonding, etc.) of two-dimensional thin film materials using incident light.

As described above, the soldering junction of the two-dimensional thin film semiconductor can provide electrical junctions (contacts), such as forming contacts with other materials, local defect fabrication for controlling optoelectronic properties, and localized trapping of chemical molecular species, including adsorption singularities of chemical molecular species.

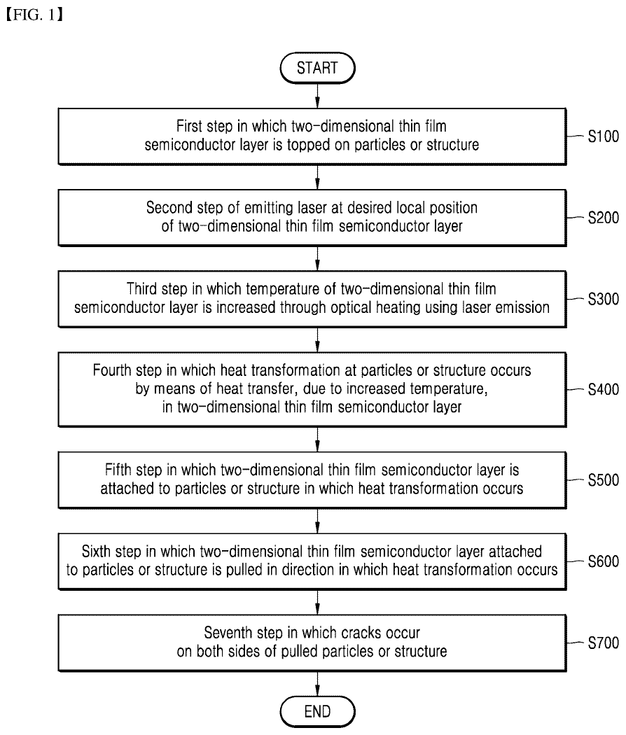

FIG. 1 is a flowchart illustrating the overall process of the method for forming junctions and defect structures in two-dimensional thin film materials using optical soldering according to an exemplary embodiment of the present disclosure.

Referring to FIG. 1, the method for forming junctions and defect structures in two-dimensional thin film materials using optical soldering according to an exemplary embodiment of the present disclosure comprises seven steps.

A detailed explanation of this process is provided below.

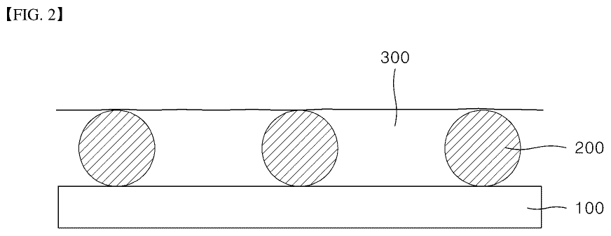

FIG. 2 is a diagram showing the state in which a two-dimensional thin film semiconductor layer is topped on a particle or a structure, in the method for forming junctions and defect structures in two-dimensional thin film materials using optical soldering according to an exemplary embodiment of the present disclosure.

Referring to FIG. 2, in the first step S100, a two-dimensional thin film semiconductor layer 300 may be topped (placed) onto particles or structures 200.

These particles or structures 200 may be positioned on a base substrate 100.

Here, the particles may be nanoparticles or microparticles.

In particular, the particles may be nanoparticles that melt at a temperature where the two-dimensional thin film semiconductor can be stably heated by light absorption. Any nanoparticles containing indium can be utilized.

For example, the particles may include indium-tin-oxide (ITO) nanoparticles (NPs), indium-zinc (IZ) nanoparticles, indium-gallium-zinc (IGZ) nanoparticles, and indium nanoparticles, as well as alloys containing indium or indium-based materials.

That is, in the present disclosure, for ease of explanation, the nanoparticles or microparticles are described as indium-tin-oxide (ITO) nanoparticles. However, the present disclosure is not limited thereto. As described above, the particles may be nanoparticles that melt at a temperature at which the two-dimensional thin film semiconductor can be stably heated by absorption of light, and any nanoparticles containing indium may be utilized.

For example, the particles may be an alloy containing indium or indium-based materials, such as indium-tin-oxide (ITO) nanoparticles (NPs), indium-zinc (IZ) nanoparticles, indium-gallium-zinc (IGZ) nanoparticles, and indium nanoparticles.

In addition, the structure may be a nanostructure or a microstructure.

In addition, the two-dimensional thin film semiconductor layer may be monolayered or multilayered.

In particular, the two-dimensional thin film semiconductor layer may be a thin film material capable of light absorption. For example, the two-dimensional thin film semiconductor layer may be one of molybdenum disulfide (MoS₂), molybdenum selenide (MoSe₂), molybdenum telluride (MoTe₂), tungsten disulfide (WS₂), or tungsten selenide (WSe₂).

That is, in the present disclosure, for ease of explanation, the two-dimensional thin film semiconductor layer is described as molybdenum disulfide (MoS₂). However, the present disclosure is not limited thereto. As described above, the two-dimensional thin film semiconductor layer may be a thin film material capable of light absorption, such as molybdenum disulfide (MoS₂), molybdenum selenide (MoSe₂), molybdenum telluride (MoTe₂), tungsten disulfide (WS₂), or tungsten selenide (WSe₂).

In addition, in the method for forming junctions and defect structures in two-dimensional thin film materials using optical soldering according to an exemplary embodiment of the present disclosure, the particle or the structure 200 may be formed by depositing a transparent electrode layer on a base substrate and then performing one of wet etching, nanoparticle spraying, or nanostructure formation.

Here, a material of the transparent electrode layer may be an indium or an alloy containing the indium.

For example, the transparent electrode layer may be an indium-tin-oxide (ITO) film, an indium-zinc (IZ) film, or an indium-gallium-zinc (IGZ) film.

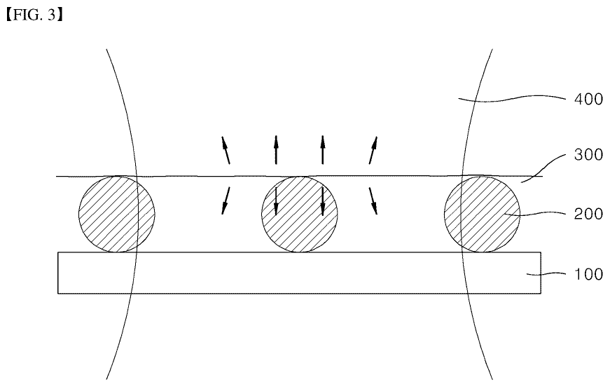

FIG. 3 is a diagram illustrating the state in which laser irradiation is applied to a designated local position of the two-dimensional thin film semiconductor layer, and the temperature of the layer increases due to optical heating induced by the laser irradiation, in the method for forming junctions and defect structures in two-dimensional thin film materials using optical soldering according to an exemplary embodiment of the present disclosure.

Referring to FIG. 3, in the second step S200, the laser 400 may be irradiated onto a designated local position of the two-dimensional thin film semiconductor layer 300. In the third step S300, the temperature of the two-dimensional thin film semiconductor layer 300 may increase due to optical heating induced by irradiation of the laser 400.

Here, by adjusting the incident power and irradiation time of the laser 400 directed at the defect site, defects can be selectively formed at the desired location.

For example, when using a 0.9 NA×100 magnification objective lens, the incident power of the laser 400 may be between 2.5 mW and 15 mW or less, and the incident time of the laser 400 may be 30 seconds or less.

In the present disclosure, various wavelengths of the laser 400 can be focused onto two-dimensional monolayer or multilayer thin film semiconductor layers to form defects at designated positions. However, in particular, a laser wavelength of 532 nm may be preferably used for enhanced focusing and defect formation.

That is, defects can be selectively formed at desired locations using the laser 400.

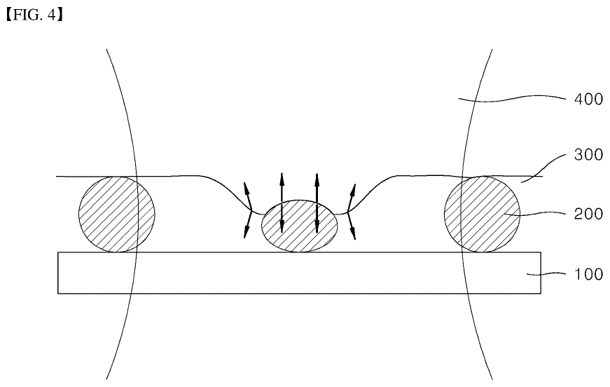

FIG. 4 is a diagram showing the state in which thermal deformation occurs in the particles or structure due to heat transfer from the heated two-dimensional thin film semiconductor layer, in the method for forming junctions and defect structures in two-dimensional thin film materials using optical soldering according to an exemplary embodiment of the present disclosure.

Referring to FIG. 4, in the fourth step S400, thermal deformation may occur in the particle or the structure 200 due to heat transfer from the two-dimensional thin film semiconductor layer 300, which has been heated by the increased temperature.

Here, the particles or structures 200 that are not subjected to irradiation of the laser 400 may maintain their shape and height to support the two-dimensional thin film semiconductor layer 300.

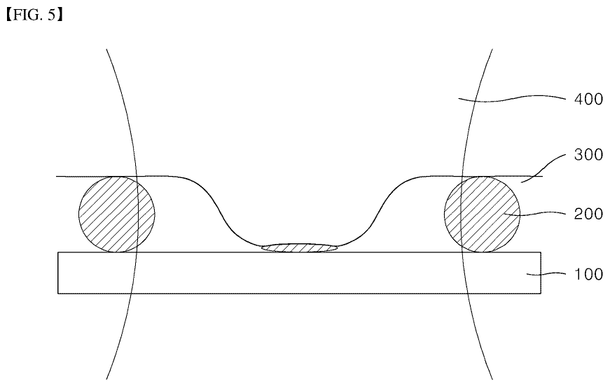

FIG. 5 is a diagram illustrating the state in which the two-dimensional thin film semiconductor layer adheres to the thermally deformed particles or structure, in the method for forming junctions and defect structures in two-dimensional thin film materials using optical soldering according to an exemplary embodiment of the present disclosure.

Referring to FIG. 5, in the fifth step S500, the two-dimensional thin film semiconductor layer 300 may be bonded to the particle or structure 200 undergoing thermal deformation.

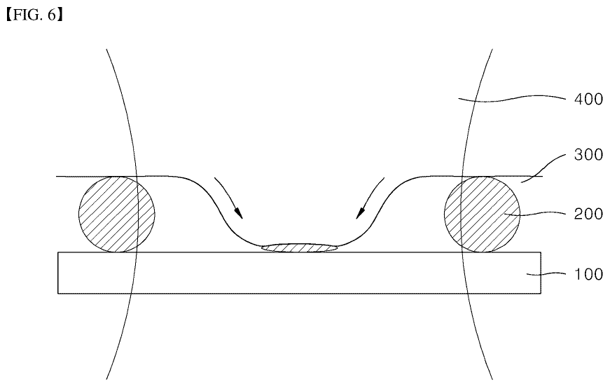

FIG. 6 is a diagram depicting the state in which the two-dimensional thin film semiconductor layer attached to the particles or structure is pulled in the direction of thermal deformation (indicated by arrows), in the method for forming junctions and defect structures in two-dimensional thin film materials using optical soldering according to an exemplary embodiment of the present disclosure.

Referring to FIG. 6, in the sixth step S600, the two-dimensional thin film semiconductor layer 300 bonded to the particle or structure 200 may be pulled in the direction where the thermal deformation occurs.

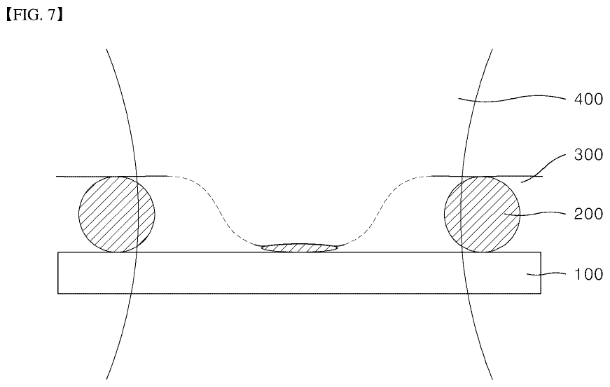

FIG. 7 is a diagram showing the state in which cracks are formed on both sides of the pulled particles or structure, in the method for forming junctions and defect structures in two-dimensional thin film materials using optical soldering according to an exemplary embodiment of the present disclosure.

Referring to FIG. 7, in the seventh step S700, cracks may occur on both sides of the pulled particle or structure 200.

As described above, the present disclosure enables localized junction (soldering) of two-dimensional thin film materials using focused light.

By joining two-dimensional materials, it is possible to achieve electrical contact, chemical molecular trapping, and optoelectronic property modulation at the designated location.

The soldering material beneath the two-dimensional material can take various forms, including nanoparticles, nanostructures, or thin films.

The soldering material is not limited to indium (In), and any material that undergoes thermal deformation at a temperature achievable through light absorption by the overlying two-dimensional material can be used.

A more detailed explanation of this process follows.

### —Optical Soldering of MoS₂ Layer on Indium-Tin-Oxide (ITO) Nanoparticles—

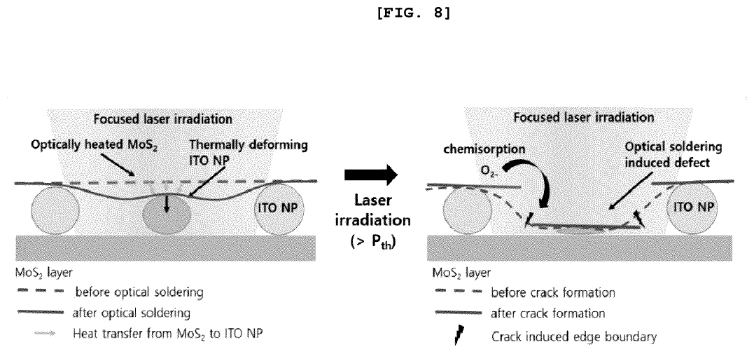

FIG. 8 is a schematic diagram illustrating the concept of optical soldering of several layers of MoS₂ on indium-tin-oxide (ITO) nanoparticles (NPs) for defect structure formation, in the method for forming junctions and defect structures in two-dimensional thin film materials using optical soldering according to an exemplary embodiment of the present disclosure.

Referring to FIG. 8, optical soldering of a two-dimensional transition metal dichalcogenide (TMD) compound may be feasible when the temperature of the indium-tin-oxide (ITO) nanoparticles exceeds their melting point due to optical heating of the MoS₂ layer.

When a laser 400 having a photon energy higher than the direct bandgap (~1.86 eV) is irradiated onto the MoS₂ multilayer, the local temperature at the focal point increases efficiently due to the low quantum efficiency (~10⁻³) of the indirect bandgap emitting photoluminescence (PL) of the multiple MoS2 layers.

Under the laser 400 irradiation of ~0.1 mW, the local temperature of a monolayer MoS₂ deposited on a substrate can rise to approximately 100 K.

The temperature of the ITO nanoparticles may increase due to heat transfer from the optically heated MoS₂ layer and, with sufficient incident optical power and irradiation duration, may reach the melting point of ITO.

The topped MoS₂ layer may be bonded strongly to the thermally deformed ITO nanoparticles.

The ITO nanoparticles exhibit adhesive properties similar to those used in thermal soldering materials.

Subsequently, as the ITO nanoparticles thermally deform and spread across the substrate, the MoS₂ layer may be pulled toward the substrate during this process.

Meanwhile, the ITO nanoparticles that are not exposed to laser irradiation may maintain their original shape and height, for supporting the topped MoS₂ layer.

Due to the low optical absorption of ITO nanoparticles in the laser wavelength region, direct optical heating of ITO nanoparticles has low possibility of optical soldering.

In order to verify the optical soldering capability of the MoS₂ layer, ITO nanoparticles were randomly dispersed using an acid wet etching process on a 20 nm-thick ITO film coated on a glass substrate.

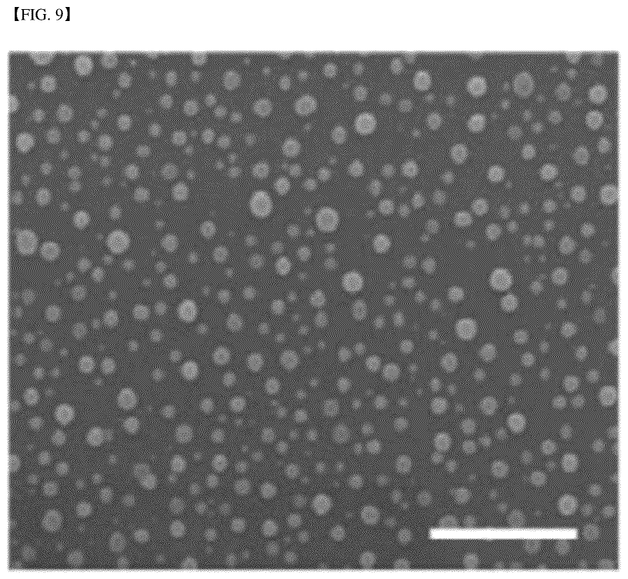

Following the etching process, ITO nanoparticles with a circular shape and preserved crystallinity, as indicated by lattice parameter analysis, were obtained. This result is confirmed in FIG. 9.

FIG. 9 is a scanning electron microscope (SEM) image of indium-tin-oxide nanoparticles with a scale bar of 500 nm, in the method for forming junctions and defect structures in two-dimensional thin film materials using optical soldering according to an exemplary embodiment of the present disclosure.

The lateral size and height of the indium-tin-oxide (ITO) nanoparticles were confirmed through scanning electron microscopy (SEM) and atomic force microscopy (AFM) measurements, respectively, where variance of 17.0 nm (lateral size) and 12.4 nm (height) may be expressed as standard deviation.

The density (~120 ea/μm²) of the ITO nanoparticles having high uniformity may be evidenced by ensuring that multiple ITO nanoparticles are present within the laser focal area during optical soldering irradiation.

The number of MoS₂ layers transferred onto the ITO nanoparticles may be estimated to be between 1 and 10, based on the height measured by the atomic force microscopy (AFM) and the spectral gap distance of the Raman peaks.

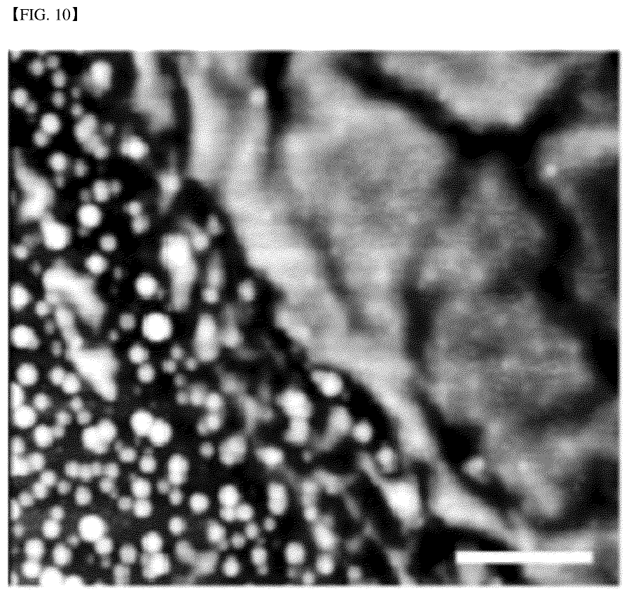

FIG. 10 is an atomic force microscope (AFM) image of indium-tin-oxide nanoparticles embedded with several layers of MoS₂ on top, in the method for forming junctions and defect structures in two-dimensional thin film materials using optical soldering according to an exemplary embodiment of the present disclosure.

Referring to FIG. 10, the atomic force microscopy (AFM) morphology of the MOS₂ layer topped on indium-tin-oxide (ITO) nanoparticles exhibits small, lightly bright spots, which suggest non-conformal contact between the ITO nanoparticles and the MOS₂ layer. This non-conformal contact may be undesirable for efficient dissipation of heat of the optically heated MoS₂ layer.

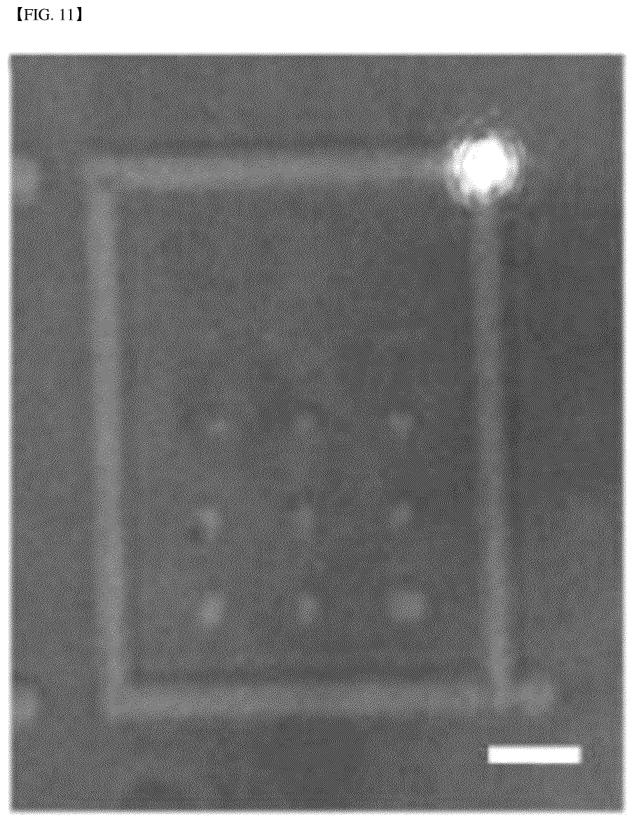

FIG. 11 is an image captured in the bright field (BF) mode.

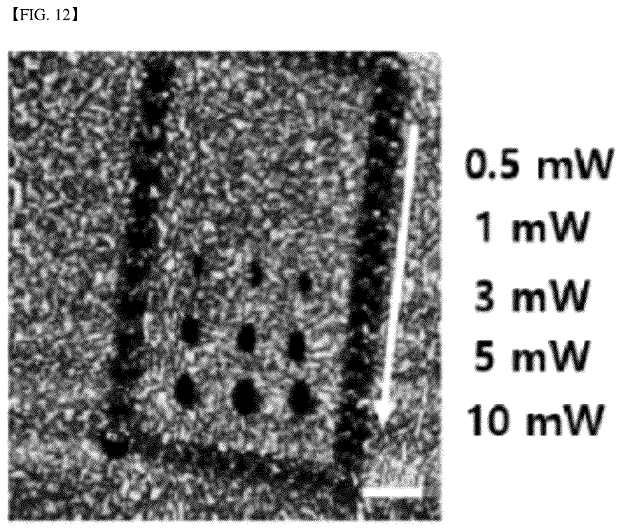

In addition, FIG. 12 is an atomic force microscope (AFM) image showing the defect structures induced by optical soldering after irradiation with a focused 532 nm laser for 15 seconds at different incident power levels of 0.5 mW, 1 mW, 3 mW, 10 mW, and 15 mW along an arrowed path, in the method for forming junctions and defect structures in two-dimensional thin film materials using optical soldering according to an exemplary embodiment of the present disclosure.

Referring to FIGS. 11 and 12, a focused 532 nm laser 400 may be irradiated on the MoS₂ layer overlying indium-tin-oxide (ITO) nanoparticles during 30 seconds for varying the incident optical power to induce optical soldering.

When the incident optical power exceeds 3 mW, a circular defect structure may be formed at the laser focus, as observed in both bright-field optical images and atomic force microscopy (AFM) morphology.

In contrast, the focal region irradiated with lower optical powers (0.5 mW, 1 mW) may not exhibit characteristics of an optical soldering-induced defect structure.

The shape of the defect structures induced by optical soldering may be similar to the cross-section of the focused incident beam.

As shown in FIGS. 11 and 12, the shape of the defect structures in the MoS₂ layer is not limited to circular forms, but instead follows the focused beam path, leading to the formation of trench-like structures.

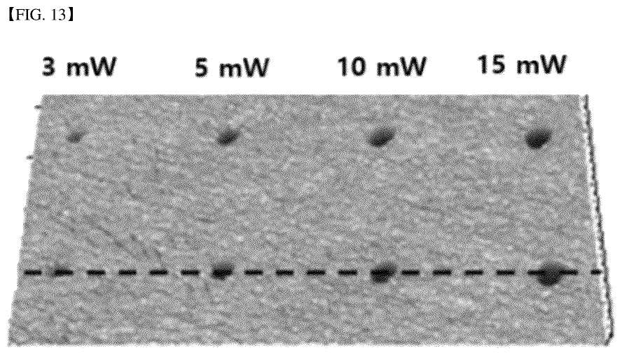

FIG. 13 is a diagram illustrating the atomic force microscope morphology of the MoS₂ layer processed through optical soldering, in the method for forming junctions and defect structures in two-dimensional thin film materials using optical soldering according to an exemplary embodiment of the present disclosure.

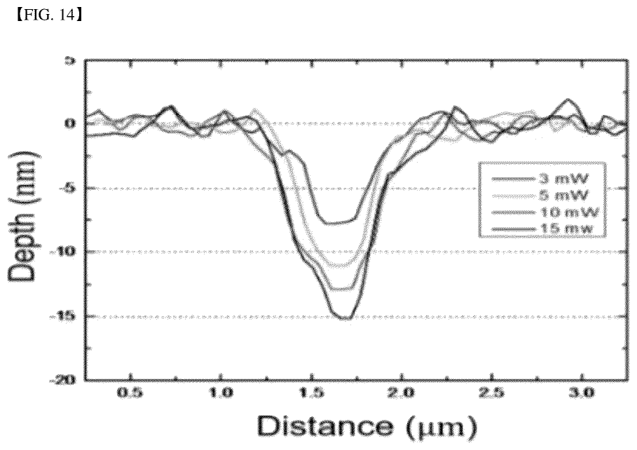

In addition, FIG. 14 is a graph showing the cross-sectional profile obtained along the black dotted line in the central region of the defect structure, in the method for forming junctions and defect structures in two-dimensional thin film materials using optical soldering according to an exemplary embodiment of the present disclosure.

Referring to FIGS. 13 and 14, the depth of the defect structure may be measured by the atomic force microscopy (AFM) at the moment when the probe reaches the bottom of the defect structure.

The overlapping cross-sectional profiles from 3D atomic force microscopy (AFM) morphology analysis clearly demonstrate the dependence of defect structure depth on incident optical power.

The depth of the defect structure corresponds to the average height of the underlying indium-tin-oxide (ITO) nanoparticles and increases monotonically up to 15 nm as a function of incident optical power.

The area of the localized defect structure increases as a function of incident optical power, which is attributed to the Gaussian profile of the incident beam.

At higher incident optical power, the Gaussian beam provides a wider focal area that exceeds the optical power threshold for optical soldering.

For a control experiment, a laser beam was focused onto an MoS₂ layer transferred onto a bare ITO substrate under the same configuration but without ITO nanoparticles. However, no optical soldering-induced defect structures were observed.

This is because, in contrast to the separated ITO nanoparticles, the effective contact area between the planar substrate and the MoS₂ layer is larger, which facilitates more efficient heat dissipation.

### —Analysis of TEM Cross-Sectional Images of Defects Induced by Optical Soldering

In order to investigate the attachment mechanism of the MoS₂ layer to the substrate containing indium-tin-oxide (ITO) nanoparticles, transmission electron microscopy (TEM) cross-sectional images of the MoS₂ layer-ITO nanoparticle interface were obtained.

This interface can be clearly identified through the overlay of transmission electron microscopy (TEM) and energy-dispersive X-ray (EDX) images, where energy filters are centered on the respective composite elements: the MoS₂ layer (Mo, S) and the ITO nanoparticles (In, Tin, Oxide).

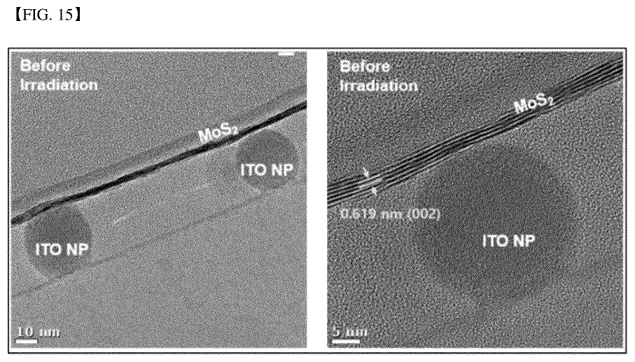

FIG. 15 is a transmission electron microscope (TEM) image of the cross-section of an indium-tin-oxide nanoparticle with several embedded layers of MoS₂ before laser irradiation, in the method for forming junctions and defect structures in two-dimensional thin film materials using optical soldering according to an exemplary embodiment of the present disclosure.

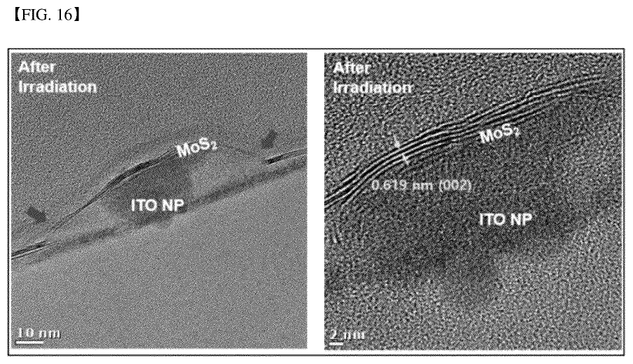

In addition, FIG. 16 is a transmission electron microscope (TEM) image of the cross-section of an indium-tin-oxide nanoparticle with several embedded layers of MoS₂ after laser irradiation, in the method for forming junctions and defect structures in two-dimensional thin film materials using optical soldering according to an exemplary embodiment of the present disclosure.

Referring to FIGS. 15 and 16, it is clearly observed that the MoS₂ layer forms a uniform bonding to the thermally deformed indium-tin-oxide (ITO) nanoparticles after laser irradiation (5 mW, 30 seconds of duration time), in comparison to the case where no laser irradiation is performed.

Despite the uniform bonding of the MoS₂ layer on the deformed ITO nanoparticles, neither the interlayer spacing between the MoS₂ layers nor the number of MoS₂ layers changes, as confirmed in TEM images.

This observation aligns with the Raman spectrum obtained from optical soldering-induced defect structures, which exhibits negligible changes in the spectral gap between the E2g and Alg vibrational modes, compared to that of the original MoS₂ layer.

In order to induce defect formation (ablation) in a two-dimensional material on a substrate, a significantly higher incident laser power is required.

In the defect structures induced by optical soldering, cracks in the MoS₂ layer are observed around the optically deformed ITO nanoparticles.

These cracks are indicated by red arrows in FIG. 16.

In two-dimensional materials, such cracks result from positional displacement within the 2D lattice, which creates abundant sites for the adsorption of various chemical species.

This suggests that the cracks in the optically soldered MoS₂ layer originate from localized stress concentrated at the hinge region between the ITO nanoparticles and the substrate.

During the optical soldering process, the vertical height of the thermally deformed ITO nanoparticles contracts, pulling the topped MoS2 layer toward the substrate.

Meanwhile, ITO nanoparticles that are either unirradiated or minimally irradiated may retain their original height, continuing to support the adjacent MoS₂ layer coated on the substrate.

The local strain (ϵ) induced in the MoS₂ layer soldered to the substrate can be estimated using Equation 1 below.

ϵ≈π²htδ/(1−σ²)λ² [Equation 1]

Here, t and σ represent the thickness of the MoS₂ layer and the Poisson's ratio, respectively.

Equation 1 as above is frequently used for the quantitative estimation of local strain in the wrinkles of two-dimensional materials, which exhibit an opposite geometric polarity (positive curvature) compared to defects (negative curvature) induced by optical soldering.

The height (h) and width (λ) of the local strain induced from the defect (h≈15 nm, λ≈90 nm) are obtained from the height of the indium-tin-oxide (ITO) nanoparticles measured by atomic force microscopy (AFM) and the distance between ITO nanoparticles measured by scanning electron microscopy (SEM).

A local strain of approximately 6.8% is induced by the MoS₂ layer optically soldered through optical soldering, which is lower than the known mechanical failure threshold strain (~10%).

Deviations in the measured strain may arise due to geometrical mismatches in the supporting shape of the indium-tin-oxide (ITO) nanoparticles. While the pristine state assumes a spherical shape, the ITO nanoparticles within the laser-irradiated region are severely deformed.

However, as the interparticle distance of ITO nanoparticles decreases, the monotonic increase trend in local strain suggests that the deformation induced by optical soldering could exceed the mechanical failure threshold within the variation range of ITO nanoparticle diameter and interparticle distance.

Meanwhile, the junction and defect structure of a two-dimensional thin film material using optical soldering according to an exemplary embodiment of the present disclosure is formed by the method for forming junctions and defect structures in two-dimensional thin film materials using optical soldering.

In particular, in the method for forming junctions and defect structures in two-dimensional thin film materials using optical soldering according to an exemplary embodiment of the present disclosure, irradiation of laser 400 at a designated local position of the two-dimensional thin film semiconductor layer 300 topped on particles or a structures 200 induces optical heating, causing heat transfer from the two-dimensional thin film semiconductor layer 300 to the particles or structures 200, thereby resulting in thermal deformation.

Here, the two-dimensional thin film semiconductor layer 300 is bonded to the thermally deformed particles or structures 200.

In addition, the two-dimensional thin film semiconductor layer 300 bonded to the particle or structure 200 is pulled in the direction of thermal deformation.

Therefore, cracks are formation on both sides of the pulled particles or structures 200.

Similarly, the junction and defect structure of a two-dimensional thin film material using optical soldering according to an exemplary embodiment of the present disclosure applies the definition of optical soldering and incorporates all the features of the method for forming junctions and defect structures in two-dimensional thin film materials using optical soldering as described above. Therefore, detailed descriptions are omitted.

Through this process, the junction and defect structure of a two-dimensional thin film material using optical soldering can be successfully formed.

As described above, according to the present disclosure, defect structures can be formed by using optical soldering, in which nanoparticles are employed as soldering materials at designated local positions of two-dimensional monolayer or multilayer thin film semiconductor materials.

In the above, although several preferred embodiments of the present disclosure have been described with some examples, the descriptions of various exemplary embodiments described in the “Specific Content for Carrying Out the Invention” item are merely exemplary, and it will be appreciated by those skilled in the art that the present disclosure can be variously modified and carried out or equivalent executions to the present disclosure can be performed from the above description.

In addition, since the present disclosure can be implemented in various other forms, the present disclosure is not limited by the above description, and the above description is for the purpose of completing the disclosure of the present disclosure, and the above description is just provided to completely inform those skilled in the art of the scope of the present disclosure, and it should be known that the present disclosure is only defined by each of the claims.

### INDUSTRIAL APPLICABILITY

According to the present disclosure, defect structures can be formed using optical soldering, where nanoparticles are employed as soldering materials at designated local positions of two-dimensional monolayer or multilayer thin film semiconductor materials.

In addition, the present disclosure enables localized junction (soldering) of two-dimensional thin film materials using focused light.

Furthermore, by joining two-dimensional materials, the present disclosure allows for electrical contact formation, chemical molecular trapping, and optoelectronic property modulation at the designated location.

Moreover, the soldering material beneath the two-dimensional material can take various forms, including nanoparticles, nanostructures, and thin films.

1. A method for forming junction and defect structure of two-dimensional thin film material by using optical soldering, wherein a nanoparticle is used as soldering material at a designated local position of a thin film semiconductor material, the method comprising:
a first step in which a two-dimensional thin film semiconductor layer is topped on a particle or a structure;
a second step of irradiating laser at a designated local position of the two-dimensional thin film semiconductor layer;
a third step in which a temperature of the two-dimensional thin film semiconductor layer increases through optical heating by irradiation of the laser; and
a fourth step in which thermal deformation occurs in the particle or the structure due to heat transfer of the two-dimensional thin film semiconductor layer by the temperature increased.

2. The method of claim 1, further comprising:
a fifth step in which the two-dimensional thin film semiconductor layer is bonded to the particle or the structure in which the thermal deformation occurs.

3. The method of claim 2, further comprising:
a sixth step in which the two-dimensional thin film semiconductor layer bonded to the particle or the structure is pulled in a direction where the thermal deformation occurs.

4. The method of claim 3, further comprising:
a seventh step in which a crack occurs on both sides of the pulled particle or the pulled structure.

5. The method of claim 1,
wherein the particle is a nanoparticle or a microparticle.

6. The method of claim 1,
wherein the structure is a nanostructure or a microstructure.

7. The method of claim 1,
wherein the two-dimensional thin film semiconductor layer is monolayered or multilayered.

8. The method of claim 1,
wherein the particle is a nanoparticle that melts at a temperature at which the two-dimensional thin film semiconductor can be heated by absorption of light.

9. The method of claim 3,
wherein the particle or the structure not subjected to optical irradiation by the laser maintains a shape and a height to support the two-dimensional thin film semiconductor layer.

10. The method of claim 1,
wherein the two-dimensional thin film semiconductor layer is a thin film material in which absorption of light occurs.

11. The method of claim 1,
wherein an incident power of the laser is between 2.5 mW and 15 mW or less, and
wherein an incident time of the laser is 30 seconds or less.

12. The method of claim 1,
wherein the particle or the structure is formed by depositing a transparent electrode layer on a base substrate and then performing one of wet etching, nanoparticle spraying, or nanostructure formation.

13. The method of claim 12,
wherein a material of the transparent electrode layer is an indium or an alloy containing the indium.

14. A defect structure formed by the method for forming junction and defect structure of two-dimensional thin film material by using optical soldering according to claim 1.

15. A junction and a defect structure of two-dimensional thin film material by using optical soldering, wherein a nanoparticle is used as soldering material at a designated local position of a thin film semiconductor material, characterized in that: by optical heating induced by irradiation of laser at a designated local position of a two-dimensional thin film semiconductor layer topped with a particle or a structure, thermal deformation occurs in the particle or the structure due to transfer of heat generated in the two-dimensional thin film semiconductor layer.

16. The junction and the defect structure of claim 15,
wherein the two-dimensional thin film semiconductor layer is bonded to the particle or the structure in which the thermal deformation occurs.

17. The junction and the defect structure of claim 16,
wherein the two-dimensional thin film semiconductor layer bonded to the particle or the structure is pulled in a direction where the thermal deformation occurs.

18. The junction and the defect structure of claim 17,
wherein a crack occurs on both sides of the pulled particle or the pulled structure.
